(19) United States
(12) Patent Application Publication
(10) Pub. No.: US 2018/0130943 A1
(43) Pub. Date: May 10, 2018

(54) MAGNETIC TUNNEL JUNCTION ELEMENT WITH REDUCED TEMPERATURE SENSITIVITY

(71) Applicant: GLOBALFOUNDRIES Singapore Pte. Ltd., Singapore (SG)

(72) Inventors: Vinayak Bharat NAIK, Singapore (SG); Kazutaka YAMANE, Singapore (SG); Kangho LEE, Singapore (SG)

(21) Appl. No.: 15/803,874

(22) Filed: Nov. 6, 2017

Related U.S. Application Data
(60) Provisional application No. 62/417,350, filed on Nov. 4, 2016.

(51) Int. Cl. H01L 43/08; H01L 27/22; H01L 43/10; H01L 43/12; H01F 41/14; H01F 10/32; H01F 10/14

(52) U.S. Cl. CPC H01L 43/08; H01L 27/228; H01L 43/10; H01F 10/14; H01F 41/14; H01F 10/32; H01L 43/12

(57) ABSTRACT

A magnetic tunneling junction (MTJ) with a reference layer is less temperature sensitive and is reflow compatible at 260° C. The reference layer may be a composite reference layer having n magnetic layers separated by (n−1) non-magnetic spacer layers. The reference layers may include low temperature coefficient reference layers or a combination of low temperature coefficient and high MR reference layers to produce a low temperature sensitive reference layer with good MR.

### CROSS-REFERENCE TO RELATED APPLICATIONS

This application claims the priority of U.S. Provisional Application No. 62/417,350 (Attorney Docket No. GFSP2016PRO115US0), entitled “Reference Layer For Magnetoresistive Memories” filed on Nov. 4, 2016. In addition, this application is cross-referenced to U.S. application Ser. No. 15/712,109 (Attorney Docket No. GFSP2016NAT114US0), entitled “High Energy Barrier Perpendicular Magnetic Tunnel Junction Element With Reduced Temperature Sensitivity”, filed on Sep. 21, 2017, which claims the priority of U.S. Provisional Application No. 62/416,719 (Attorney Docket No. GFSP2016PRO114US0), entitled “Reflow Compatible Crystalline Free Layers In Magnetic Tunnel Junction” filed on Nov. 3, 2016. All disclosures are incorporated herewith by reference in their entireties for all purposes.

### BACKGROUND

A magnetic tunnel junction (MTJ) is used in a magnetic random access memory (MRAM) to store information. A MTJ typically has at least two magnetic layers separated by a tunneling barrier layer. The tunneling barrier layer allows electrons to tunnel from one magnetic layer to the other. Data storage is achieved by the directional change, from parallel to antiparallel, or vice versa, of magnetic layers in a MTJ.

Information is stored in one of the magnetic layer, which is called a free layer or a storage layer. An important aspect of the MRAMs is to stably store information. However, conventional packaging processing used to form MRAM chips requires temperatures of about 260° C. Exposure of the MTJs to such high temperatures degrades the stability of information stored. This creates information storage stability problems as the embedded MRAM applications often have the MTJs pre-programmed with information prior to packaging.

From the foregoing discussion, it is desirable to provide a reliable MRAM device which can stably store information at backend packaging processing temperatures. This eliminates the high temperature concern for the MTJ element.

### SUMMARY

Embodiments of the present disclosure generally relate to devices with MTJ elements and method of forming thereof. In one embodiment, a method for forming a device is disclosed. The method includes providing a substrate comprising circuit component formed on a substrate surface and performing back-end-of-line (BEOL) processing to form a BEOL dielectric layer, which includes a plurality of interlevel dielectric (ILD) levels, over the substrate. The method is followed by forming a perpendicular magnetic tunnel junction (pMTJ) stack between adjacent ILD levels of the BEOL dielectric layer such that the pMTJ stack is disposed between top and bottom electrodes. Forming of the pMTJ stack includes forming various layers of the pMTJ on the bottom electrode such as a magnetic fixed layer, a first tunnelling barrier layer, and a magnetic free layer. Particularly, the magnetic fixed layer includes a magnetic reference layer with a low temperature coefficient (TempCo) and high magnetic ratio (MR).

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

The accompanying drawings, which are incorporated in and form part of the specification in which like numerals designate like parts, illustrate preferred embodiments of the present disclosure and, together with the description, serve to explain the principles of various embodiments of the present disclosure.

FIGS. 1a-1b show simplified diagrams of parallel state and anti-parallel state of bottom pinned and top pinned perpendicular MTJ (pMTJ) modules of a magnetic memory cell;

FIG. 2a shows a schematic diagram of an exemplary embodiment of a magnetic memory cell;

FIG. 2b shows a schematic diagram of an exemplary array of magnetic memory cells;

FIGS. 3a-3d show simplified cross-sectional views of embodiments of a pMTJ stack of a magnetic memory cell;

FIGS. 4a-4b show more detailed cross-sectional views of embodiment of a pMTJ stack of a magnetic memory cell;

FIGS. 5a-5c show cross-sectional views of embodiments of a composite magnetic reference layer;

FIG. 6 shows an exemplary cross-sectional view of an embodiment of a device; and

FIGS. 7a-7e show cross-sectional views of an embodiment of a process for forming an exemplary memory cell.

### DETAILED DESCRIPTION

Embodiments of the present disclosure generally relate to semiconductor devices and methods for forming a semiconductor device. For example, the semiconductor device is a memory device. For example, the memory device may be magnetoresistive random access memory (MRAM) device. Other types of memory devices may also be useful. A magnetoresistive memory cell includes a magnetic tunneling junction (MTJ) storage unit. For example, the MTJ storage unit is a perpendicular MTJ (pMTJ) stack. The pMTJ stack of the present disclosure includes a reference layer that is less temperature sensitive and is reflow compatible, e.g., enough stability of magnetization at 260° C. during the reflow process. Such memory devices, for example, may be incorporated into standalone memory devices including, but not limited to, USB or other types of portable storage units, or integrated circuits (ICs), such as microcontrollers or system on chips (SoCs). The devices or ICs may be incorporated into or used with, for example, consumer electronic products or other types of products.

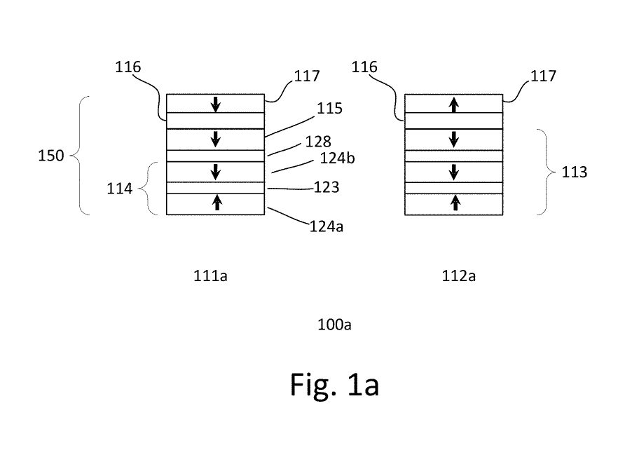

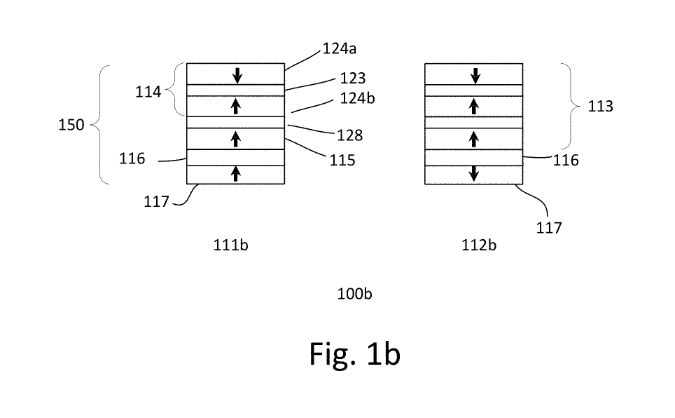

FIG. 1a shows simplified diagrams of parallel state and anti-parallel state of a bottom pinned perpendicular MTJ module 100a of a magnetic memory cell. The embodiment shows a simplified cross-sectional view of a bottom pinned pMTJ unit or module 100a of a magnetic memory cell. The MTJ module includes a pMTJ element or stack 150 disposed between a bottom electrode and a top electrode. The bottom electrode is proximate to the substrate on which the memory cell is formed while the top electrode is distal from the substrate.

The MTJ element includes a magnetically fixed (pinned) layer 113, a tunneling barrier layer 116 and a magnetically free layer 117. In one embodiment, the magnetically fixed layer 113 is disposed below the magnetically free layer 117, forming a bottom pinned pMTJ stack. The magnetic orientation or magnetization of the fixed layer 113 is fixed in a first perpendicular direction. The term perpendicular direction, for example, refers to the direction of the magnetic field which is perpendicular to the surface of a substrate or perpendicular to the plane of the layers of the MTJ module.

The magnetic fixed layer includes a synthetic antiferromagnetic (SAF) layer 114. The SAF layer includes first and second magnetic layers 124a and 124b separated by an exchange coupling layer 123. The first and second magnetic layers of the SAF layer have opposite directions of magnetization. For example, as shown, the first magnetic layer 124a has a first magnetization direction which is in the upward direction while the second magnetic layer 124b has a second magnetization direction which is in the opposite or downward direction. A reference layer 115 is disposed over the SAF layer. The reference layer and the SAF layer are separated by a spacer layer 128. The reference layer has a magnetization direction which is in the same direction as the second magnetic layer of the SAF layer. For example, the reference layer has a second magnetization direction. The SAF layer, for example, pins the magnetization of the reference layer in the second magnetization direction.

As shown, the first magnetization direction is in an upward perpendicular direction away from the bottom electrode. Providing the first magnetization direction which is in a downward perpendicular direction towards the bottom electrode may also be useful. As for the magnetic orientation or magnetization of the free layer 117, it may be programmed to be in a first or same direction as the reference layer 115 or in a second or opposite direction as the reference layer 115.

For example, as shown by structure 111a, the magnetic orientation or magnetization of the free layer 117 is programmed to be in the first or parallel magnetization direction as the reference layer 115. The corresponding MTJ electrical resistance between the free layer 117 and the reference layer 115 is denoted as RP. Structure 112a illustrates that the magnetic orientation of the free layer 117 is programmed to be in the second or anti-parallel direction to the reference layer 115. The corresponding MTJ electrical resistance between the free layer 117 and the reference layer 115 is denoted as RAP. The resistance RAP is higher than the resistance RP, corresponding to first and second states of the memory cell.

FIG. 1b shows simplified diagrams of parallel state and anti-parallel state of a top pinned pMTJ module of a magnetic memory cell. The embodiment shows a simplified cross-sectional view of a top pinned pMTJ unit or module 100b of a magnetic memory cell. The MTJ module includes a pMTJ element or stack 150 disposed between a bottom electrode and a top electrode. The bottom electrode is proximate to the substrate on which the memory cell is formed while the top electrode is distal from the substrate. The top pinned pMTJ unit is similar to the bottom pinned pMTJ unit of FIG. 1a. Common elements may not be described or described in detail. As shown, the free layer 117 is disposed below the fixed layer 113. In structure 111b, the free layer 117 is programmed to have a same or parallel magnetization direction as the reference layer 115 while the free layer 117 in structure 112b is programmed to have an opposite or anti-parallel magnetization direction as the reference layer 115.

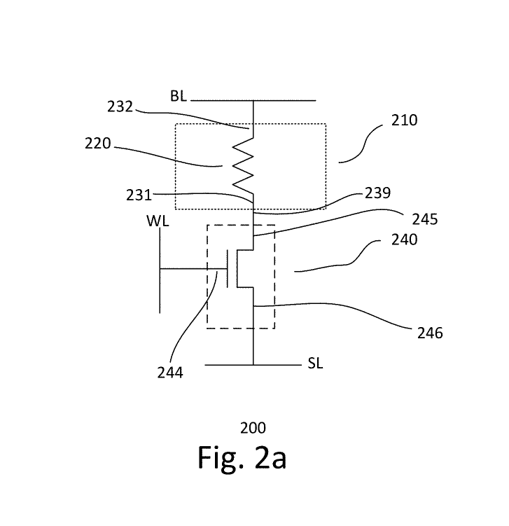

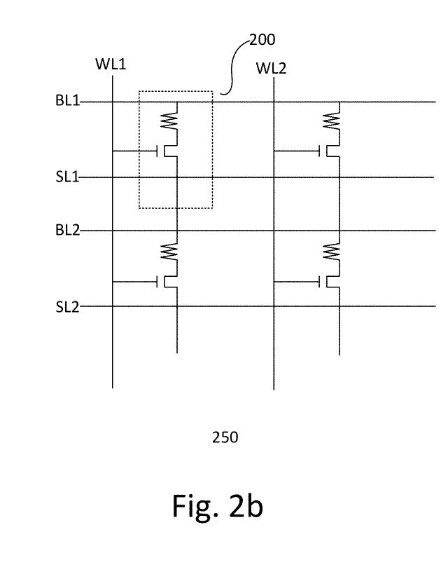

FIG. 2a shows a schematic diagram of an embodiment of a memory cell 200. The memory cell is a non-volatile memory (NVM) cell. For example, the memory cell may be a magnetoresistive memory cell. In one embodiment, the memory cell is a spin transfer torque-magnetoresistive random access memory (STT-MRAM) cell. Other suitable types of memory cells may also be useful. The memory cell includes a storage unit 210 and a cell selector unit 240. The storage unit 210 is coupled to the cell selector unit 240. For example, the storage unit 210 and the cell selector unit 240 are coupled at a first cell node 239 of the memory cell. The storage unit 210, in one embodiment, is a magnetic storage unit and includes a pMTJ stack 220. The pMTJ stack may be a bottom pinned pMTJ stack or a top pinned pMTJ stack.

The pMTJ stack includes first and second electrodes 231 and 232. The first electrode 231, for example, may be a bottom electrode while the second electrode 232 may be a top electrode. Other configurations of electrodes may also be useful. In one embodiment, the top electrode 232 of the storage unit 210 is electrically connected to a bitline (BL). The bottom electrode 231 of the storage element 210 is connected to the first cell node 239.

The cell selector unit 240 includes a selector for selecting the memory cell. The selector, for example, may be a select transistor. In one embodiment, the select transistor is a metal oxide semiconductor (MOS) transistor. In one embodiment, the selector is a n-type MOS transistor. The select transistor includes first and second source/drain (S/D) terminals 245 and 246 and a gate or control terminal 244. The S/D terminals, for example, are heavily doped regions with first polarity type dopants, defining the first type transistor. For example, in the case of a n-type transistor, the S/D terminals are n-type heavily doped regions. Other types of transistors or selectors may also be useful.

In one embodiment, the first terminal of the cell selector and the first electrode of the storage unit are commonly coupled at the first cell node. For example, the first S/D terminal 245 of the cell selector 240 is coupled to the bottom electrode 231 of the storage unit 210. The second terminal 246 of the cell selector is coupled to a source line (SL). As for the gate terminal 244, it is coupled to a wordline (WL).

FIG. 2b shows a schematic diagram of an embodiment of a memory array 250. The array includes a plurality of memory cells 200 that are interconnected. The memory cells may be similar to the memory cell described in FIG. 2a. For example, the memory cells are MRAM cells, such as STT-MRAM cells. Common elements may not be described or described in detail. Other suitable types of memory cells may also be useful.

As shown, the array includes four memory cells arranged in a 2×2 array. For example, the array is arranged to form two rows and two columns of memory cells. Memory cells of a row are interconnected by a wordline (WL1 or WL2) while memory cells of a column are interconnected by a bitline (BL1 or BL2). A S/D terminal is coupled to a source line (SL1 or SL2). Other suitable cell configurations may also be useful. Although the array is illustrated as a 2×2 array, it is understood that arrays of other sizes may also be useful.

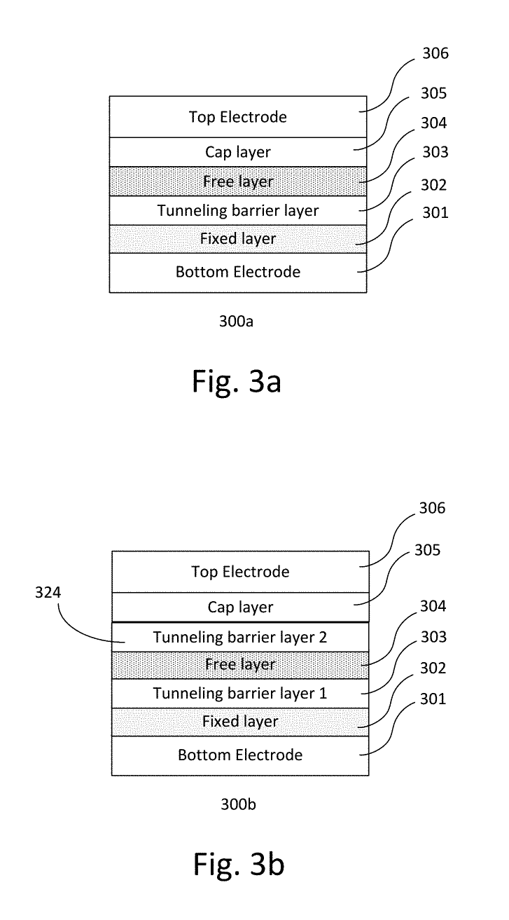

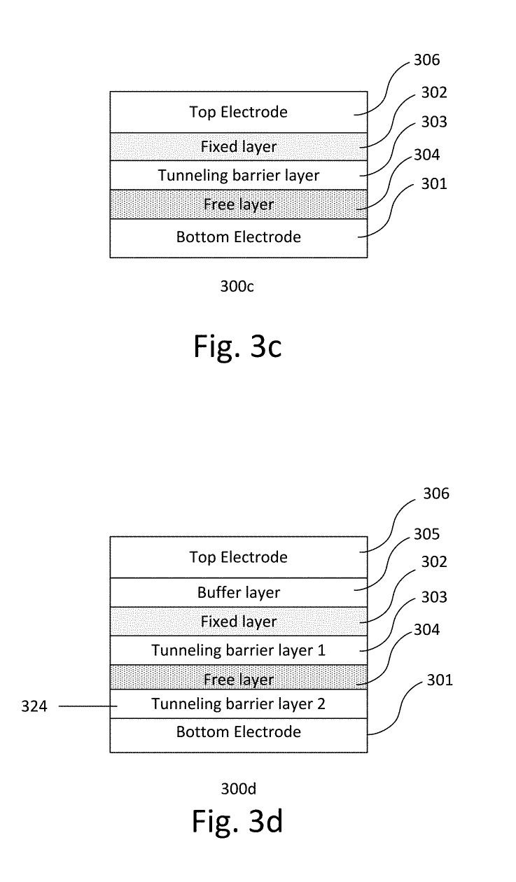

FIG. 3a shows a simplified cross-sectional view of a MTJ stack of a magnetic memory cell. The cross-sectional view may be along a bitline direction (x-axis). The MTJ stack, as shown, is a bottom pinned pMTJ stack with a stack of layers. In one embodiment, the pMTJ stack 300a is a single tunneling barrier bottom pinned pMTJ stack. The pMTJ stack may include a MTJ element disposed between a bottom electrode 301 and a top electrode 306. The electrodes may be tantalum-based (Ta-based), titanium-based (Ti-based) or tungsten-based (W-based) electrodes. For example, the electrodes may be tantalum (Ta), tantalum nitride (TaN), titanium (Ti) or titanium nitride (TiN). In one embodiment, the bottom electrode may be a TaN electrode while the top electrode may be a Ta electrode. Other types or configurations of electrodes may also be useful. The thickness of an electrode may be about 5-15 nm and may be formed by, for example, physical vapor deposition (PVD), including sputtering, or atomic layer deposition (ALD). Other thicknesses or techniques for forming the electrodes may also be useful.

The pMTJ element includes a magnetic fixed layer 302, a tunneling barrier layer 303, a magnetic free layer 304 and a cap layer 305. The layers of the pMTJ element may be sequentially formed on the bottom electrode. The stack layers, including the bottom and top electrodes, may be patterned to form a pMTJ stack of a memory cell. Other configurations of patterning the layers to form the pMTJ stack may also be useful. In one embodiment, the magnetic fixed layer 302 is disposed below the magnetic free layer 304, creating a bottom pinned pMTJ stack. In one embodiment, the magnetic free layer includes at least one as-deposited crystalline magnetic layer. The magnetic orientation or magnetization of the free layer may be programmed to be in the first or same direction as the fixed layer, or in a second or opposite direction as the fixed layer.

The tunneling barrier layer 303 is disposed between the fixed and the free magnetic layers. The tunneling barrier layer may be a metal oxide layer. The oxide layer is a non-magnetic and electrically insulating layer which is used for maintaining spin polarization during electron transit across the barrier. The tunneling barrier layer may be a crystalline magnesium oxide (MgO). Other types of tunneling barrier layers, such as an amorphous aluminum oxide (Al₂O₃), may also be used. As for the cap layer, it is disposed over the magnetic free layer. The cap layer may serve to protect the underlying free layer and to promote the perpendicular magnetic anisotropy (PMA) in the free layer. The cap layer may be a platinum (Pt), ruthenium (Ru), or Ta cap layer. Other types of cap layer, such as MgO, may also be useful. For example, the cap layer may serve as a second tunneling barrier layer or vice-versa. The cap layer may have a thickness of about 0.5-10 nm and formed by, for example, PVD, including sputtering, or ALD. Other thicknesses or forming techniques may also be useful.

The MTJ stack may include additional layers. In some cases, the MTJ stack may include a seed or underlayer (not shown) disposed on the bottom electrode. For example, the seed layer may be disposed between the bottom electrode and fixed layer. The seed layer may serve to provide a proper template for fixed magnetic layer. In one embodiment, the seed layer may include nickel (Ni), chromium (Cr), iron (Fe), cobalt (Co), iridium (Ir), Ru, Pt, W, Ta, or a combination of thereof. In some cases, the seed layer may include more than one element. For example, the seed layer may include Ru—Cr, Ru—Pt, Ru—Ir, NiFeCr, NiCr, NiW or NiTa. Other types of seed layers may also be used. The seed layer may have a thickness of about 0.2-5 nm and may be formed by, for example, PVD, including sputtering, or ALD. Other thicknesses or forming techniques may also be useful.

In another embodiment, as shown in FIG. 3b, the pMTJ stack 300b is a dual tunneling barrier bottom pinned pMTJ stack. For example, the pMTJ stack includes first and second tunneling barrier layers 303 and 324. The dual tunneling barrier pMTJ stack is similar to the single tunneling barrier bottom pinned pMTJ stack of FIG. 3a. Common elements may not be described or described in detail. As shown, the second tunneling barrier layer 324 is disposed between the free layer 304 and the cap layer 305. The second tunneling barrier layer 324 may be of the same or different materials as the first tunneling barrier layer 303. Other configurations of tunneling barrier layers may also be useful.

FIG. 3c shows a simplified cross-sectional view of another embodiment of a MTJ stack of a magnetic memory cell. The cross-sectional view may be along a bitline direction (x-axis). The MTJ stack 300c, as shown, is a single tunneling barrier top pinned pMTJ stack. The pMTJ stack is similar to the pMTJ stacks described in FIGS. 3a-3b except that it is a top pinned pMTJ stack instead of a bottom pinned pMTJ stack. Common elements may not be described or described in detail.

The pMTJ stack may include a pMTJ element disposed between a bottom electrode 301 and a top electrode 306. The pMTJ element includes a magnetic free layer 304, a tunneling barrier layer 303 and a magnetic fixed layer 302. The layers may be sequentially formed on the bottom electrode. The stack may include additional layers. For example, a buffer layer (not shown in FIG. 3c) may be disposed between the fixed layer and top electrode. The buffer layer may be a rhodium (Rh), molybdenum (Mo), hafnium (Hf), Ir, Ti, Cr, Ru, W, layer, or a combination of thereof and serves to improve crystal orientation of the fixed layer.

FIG. 3d shows a cross-sectional view of a MTJ stack of a magnetic memory cell. The MTJ stack 300d, as shown, is a dual tunneling barrier top pinned pMTJ stack. The pMTJ stack is similar to the pMTJ stacks described in FIGS. 3a-3c. Common elements may not be described or described in detail. The pMTJ stack includes a pMTJ element disposed between a bottom electrode 301 and a top electrode 306. The pMTJ element includes a second tunneling barrier layer 324, a magnetic free layer 304, a first tunneling barrier layer 303, a magnetic fixed layer 302 and a buffer layer 305. The layers may be sequentially formed on the bottom electrode.

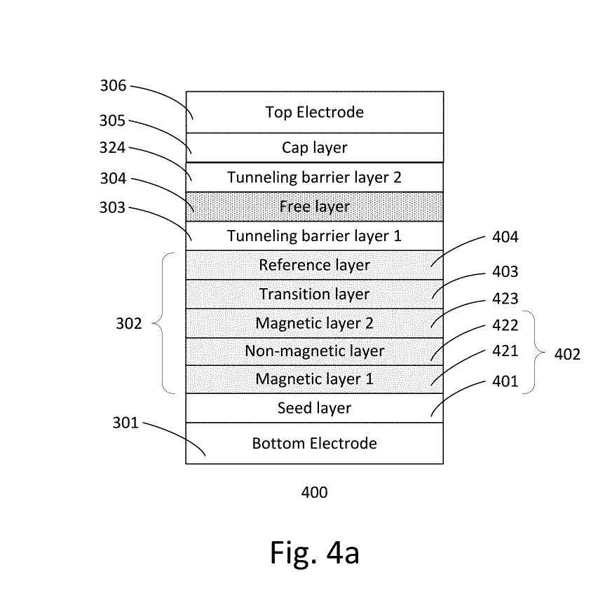

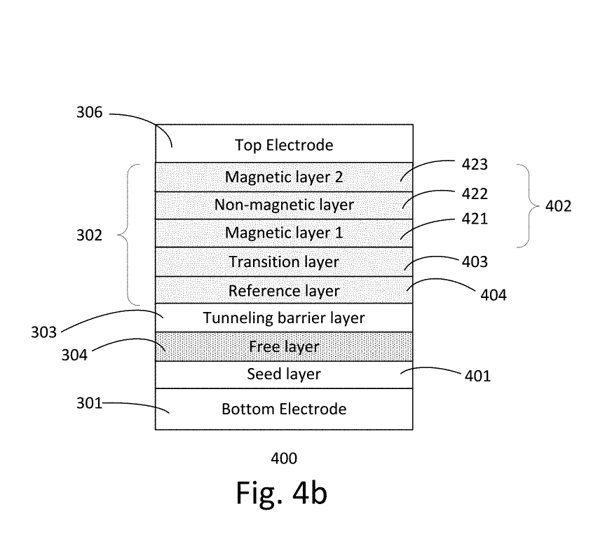

FIG. 4a shows a more detailed cross-sectional view of an embodiment of a dual tunneling barrier bottom pinned pMTJ stack of a magnetic memory cell. The pMTJ stack is similar to those described in FIGS. 3a-3b. Common components may not be described or described in detail. As shown, the pMTJ stack 400 includes a pMTJ element disposed between a bottom electrode 301 and a top electrode 306. The pMTJ element includes a seed layer 401, a fixed magnetic layer 302, a first tunneling barrier layer 303, a free magnetic layer 304, a second tunneling barrier layer 324 and a cap layer 305.

As for the seed layer 401, it may be disposed on the bottom electrode 301. The seed layer may include a planar top surface for ensuring good adhesion to the subsequent layers. The seed layer may include Ni, Cr, Ru, Fe, Co, Ir, W, Ta, Pt or a combination thereof. In one embodiment, the seed layer may include at least 2 selected from the group which include Ni, Cr, Ru and Pt. Other types or configurations of materials suitable for used as the seed layer in the pMTJ stack may also be useful.

The magnetic fixed layer 302 may be disposed on the seed layer 401. The fixed layer, as shown, includes a hard magnetic (HM) layer 402, a transition layer 403 and a reference layer 404. The HM layer 402 may be a synthetic antiferromagnetic (SAF) layer. The SAF layer may include a first magnetic layer 421 and a second magnetic layer 423. The magnetic layers may be an alloy magnetic layer or a multilayer. The first and the second magnetic layers may be formed with the same or different materials. For example, the first and second magnetic layers may be Co, Pt, Ni or a combination thereof. Other magnetic layers, such as other types of Co-alloy layers, may also be useful. A non-magnetic metal layer 422 may be disposed between the first and second magnetic layers, to facilitate the exchange coupling field between the two magnetic layers. For example, the non-magnetic metal layer may be a Ru, Ir, Cr, NiCr, Rh layer, or a combination of thereof. Other non-magnetic metal layers may also be useful.

The magnetic and non-magnetic layers may be formed by, for example, PVD, including sputtering, or ALD. The thickness of the magnetic layers may be about 1-5 nm each and the non-magnetic metal layer may be about 0.1-0.5 nm. Other forming techniques and thicknesses for the layers may also be useful.

The transition layer 403 is disposed on the magnetic layer 402. The transition layer includes a non-magnetic layer. The transition layer may include vanadium (V), zirconium (Zr), niobium (Nb), Ti, Cr, Mo, Hf, Ta, W, Al or a combination thereof. The transition layer may serve to govern the growth of the subsequently formed layers. Other non-magnetic materials may also be useful. The transition layer may be formed by, for example, PVD, including sputtering, or ALD. The thickness of the layer may be about 0.2-1 nm each and the non-magnetic metal layer may be about 0.1-0.5 nm. Other techniques for forming the layer or thicknesses may also be useful.

The reference or polarizer layer 404 is disposed on the transition layer 403. The reference layer is configured to have lower temperature sensitive moment. In one embodiment, the reference layer may include a single magnetic layer. In other embodiment, the reference layer may be a composite reference layer with multiple magnetic layers separated by non-magnetic spacer layer or layers. For example, a reference layer may include n magnetic layers separated by n−1 non-magnetic spacer layers. In the case of a single magnetic reference layer (n=1), a non-magnetic spacer layer may not be needed (n=0). In the case of a composite reference layer, the magnetic reference layer 1 (n=1) is proximate to the HM layer and the magnetic reference layer n (n=n) is proximate to the tunneling barrier layer. For example, the tunneling barrier layer is disposed between the free layer and the reference layer n. The spacer layer may be provided for facilitating coupling between two magnetic reference layers. The number n, in one embodiment, may be 1-3. Providing other values of n may also be useful. For example, n may be greater than 3.

The thickness of a magnetic reference layer may be about 0.2-1.5 nm and the thickness of a non-magnetic spacer layer may be about 0.1-0.5 nm. Other thicknesses may also be useful. It is understood that the different reference and spacer layers may have different thicknesses. The magnetic and non-magnetic layers may be formed by, for example, PVD, including sputtering, or ALD. Other forming techniques may also be useful.

A non-magnetic spacer layer may be a Ta, Mo or W spacer layer. Other types of spacer layers, including Ir and Zr may also be useful. A non-magnetic spacer layer may also include a combination of the various spacer materials, such as Ta, Mo, W, Ir and Zr. As discussed, a spacer layer facilitates coupling between two magnetic reference layers. A non-magnetic spacer layer preferably should be sufficiently thin to provide strong coupling with good stiffness to reduce or result in low temperature sensitivity.

As discussed, the reference layer is configured to have low temperature sensitivity. For example, the reference layer, whether single or with multiple magnetic reference layers, is configured to have almost constant temperature response for both magnetic moment (Mₛ) and magnetic anisotropy (Hₖ). This results in a low coupling field (H_{cpl}) from room temperature to reflow temperature. For example, both Mₛ and effective perpendicular magnetic anisotropy (K_{eff}) are less sensitive to temperature. In one embodiment, the composite reference layer has a low H_{cpl}. The H_{cpl} is close to zero at the reflow temperature. In one embodiment, the H_{cpl} may be about 0 Oe at room temperature, such as 25° C. At reflow temperature, which may be about 260° C., the composite reference layer has low H_{cpl}, such as less than 20 Oe. A low H_{cpl} improves data retention reliability.

A reference magnetic layer may include a CoFe-based magnetic reference layer. For example, the reference layer may be a CoFeB or a CoFeB-based layer. Other types of CoFe-based reference layers may also be useful. In one embodiment, the reference layer includes a low temperature coefficient (TempCo) magnetic layer. A low TempCo magnetic reference layer has less temperature sensitive magnetic properties. For example, the Mₛ and K_{eff} of a low TempCo magnetic reference layer is less affected by increasing temperature as compared to conventional CoFe-based reference layers.

In the case of a single reference layer, the CoFe-based magnetic reference layer is configured to be a low TempCo CoFe-based layer with good spin polarization to improve magnetoresistance ratio (MR). Tuning the CoFe-based layer may be achieved by using different compositions of Co, Fe. For example, a CoFe-based layer having a 50:50 of Co:Fe has been found to have optimal TempCo. In one embodiment, tuning a CoFeB or CoFeB-based layer may be achieved by using different compositions of Co, Fe and B. For example, lower compositional amounts of B may result in smaller TempCo.

A low TempCo magnetic reference layer may, alternatively be a samarium (Sm) based magnetic reference layer. The Sm-based layer may include a doped Sm or SmCo₅. The Sm-based layer may be doped with dysprosium (Dy), Cu, Mo, W, B, Fe, Co, Zr or a combination thereof. Doping the Sm-based layer with other types of dopants may also be useful. In other embodiments, the low TempCo magnetic reference layer may be Sm doped with at least one transition metal (TM). For example, the low TempCo magnetic reference layer may be a SmTM layer, such as Sm₂TM₁₇ layer. Other types of SmTM layers may also be useful.

In the case of a composite reference layer, it includes multiple magnetic reference layers separated by a non-magnetic metal spacer layer. It is understood that the magnetic reference layers may be formed of the same or different types of magnetic layers. In addition, it can be formed of the same type of magnetic layers, but with different compositions for the elements. Likewise, in the case of more than 1 non-magnetic metal spacer layers, they can be formed of the same or different metal layers. Tuning the spin polarization or MR and TempCo of a magnetic layer, as discussed, can be achieved by material as well as compositions of the elements of the layer.

In addition, the thickness of the layer may be tuned for MR and TempCo. For example, in the case of a CoFe-based magnetic layer, thickness may affect MR and TempCo. The thicker the layer, the higher the MR. A thicker layer has also been found to reduce temperature sensitivity. Conversely, a thinner layer has lower MR and higher TempCo.

The various magnetic layers of the composite reference layer can be tuned to produce a composite reference layer with low TempCo. In addition, the composite reference layer has good MR. In one embodiment, magnetic layers close to the tunnel barrier layer are tuned to have high MR while layers away from the tunnel barrier layer are tuned to have low TempCo. For example, the magnetic layer closest to the tunnel barrier layer is preferably tuned to have the highest MR. Magnetic layers not closest to the tunnel barrier layer may preferably be tuned to have decreasing TempCo, with the magnetic layer farthest away having the lowest TempCo. Other configurations of the different magnetic layers of the composite reference layer may also be useful.

The first tunneling barrier layer 303 is disposed between the reference layer 404 and the free layer 304. The second tunneling barrier layer 324 may be disposed between the free layer 304 and the cap layer 305. The tunneling barrier layers may be, for example, MgO layers. Other types or configurations of tunneling barrier layers may also be useful. For example, the pMTJ stack may be a single barrier pMTJ stack with only a first tunneling barrier disposed between the reference layer and free layer, such as that shown in FIG. 3a. The tunneling barrier layer may be formed by, for example, PVD, including sputtering, or ALD. The thickness of the layer may be about 0.8-1.2 nm. Other forming techniques and thicknesses for the tunneling barrier layer may also be useful.

The free or storage layer 304 is disposed over the first tunneling barrier layer 303. The storage layer is a magnetic layer. In one embodiment, the storage layer may be a CoFe-based or a CoFeB-based layer. The storage layer may be a single layer or a composite layer. The thickness of the storage layer may be about 10-20 Å to maintain PMA. In the case of a composite free layer, it may include a magnetic/non-magnetic/magnetic stack. The magnetic layers may be any combination of CoFe-based, including CoFeB-based layers, while the non-magnetic layer may be Pd or Pt. Other types of composite free layers may also be useful. The magnetic free layer, for example, includes at least one as-deposited crystalline magnetic layer. Providing a composite magnetic free layer which includes a plurality of as-deposited crystalline magnetic layers or a combination of as-deposited crystalline and as-deposited amorphous magnetic layers, as described in U.S. application Ser. No. 15/712,109 (Attorney Docket No. GFSP2016NAT114US0), which is herein incorporated by reference for all purposes, may also be useful. The layers of the composite storage layers may be about 1-3 nm each and may be formed by, for example, PVD, including sputtering, or ALD. Other techniques for forming the storage layer or thicknesses may also be useful.

The cap layer 305 is disposed on the second tunneling barrier layer 324. The cap layer may serve to protect the underlying free layer and to promote the PMA in the free layer. The cap layer may be a Pt, Ru, or Ta cap layer. Other types of cap layer, such as MgO, may also be useful. In one embodiment, for example, the second tunneling barrier layer may serve as the cap layer. As for the top electrode layer 306, it is disposed on the cap layer.

As described, the MTJ stack is a bottom pinned dual tunneling barrier MTJ stack with first and second tunneling barrier layers. The MTJ stack may be modified to be a bottom pinned single tunneling barrier MTJ stack, similar to that described in FIG. 3a.

FIG. 4b shows a more detailed cross-sectional view of an embodiment of a single tunneling barrier top pinned pMTJ stack of a magnetic memory cell. The pMTJ stack is similar to those described in FIGS. 3a-3d and 4a. Common components may not be described or described in detail.

The pMTJ stack is disposed between bottom and top electrodes 301 and 306. The pMTJ stack may include a seed layer 401, a magnetic free layer 304, a tunneling barrier layer 303 and a fixed magnetic layer 302. The layers may be sequentially formed on the bottom electrode and patterned to form the pMTJ.

The seed layer 401 may be disposed on the bottom electrode 301. The magnetic free layer 304 may be disposed on the seed layer 401. The tunneling barrier layer 303 is disposed on the free layer 304. The tunneling barrier layer may be, for example, a MgO layer. Other types or configurations of tunneling barrier layers may also be useful. For example, the pMTJ stack may be a dual tunneling barrier pMTJ stack with first tunneling and second barrier layers, such as that shown in FIG. 3d.

The fixed layer may be disposed on the tunneling barrier layer. As shown, the fixed layer includes a hard magnetic (HM) layer 402, a transition layer 403 and a reference layer 404. The reference layer, in one embodiment, includes a composite reference layer, as described in FIG. 4a. The HM layer 402 may be a synthetic antiferromagnetic (SAF) layer. The SAF layer may include a first magnetic layer 421 and a second magnetic layer 423. The top electrode 306 is disposed over the fixed layer. For example, the top electrode is disposed on the second magnetic layer 423 of the SAF layer.

As described, the MTJ stack is a top pinned single tunneling barrier MTJ stack. The MTJ stack may be modified to be a top pinned dual tunneling barrier MTJ stack, similar to that described in FIG. 3d.

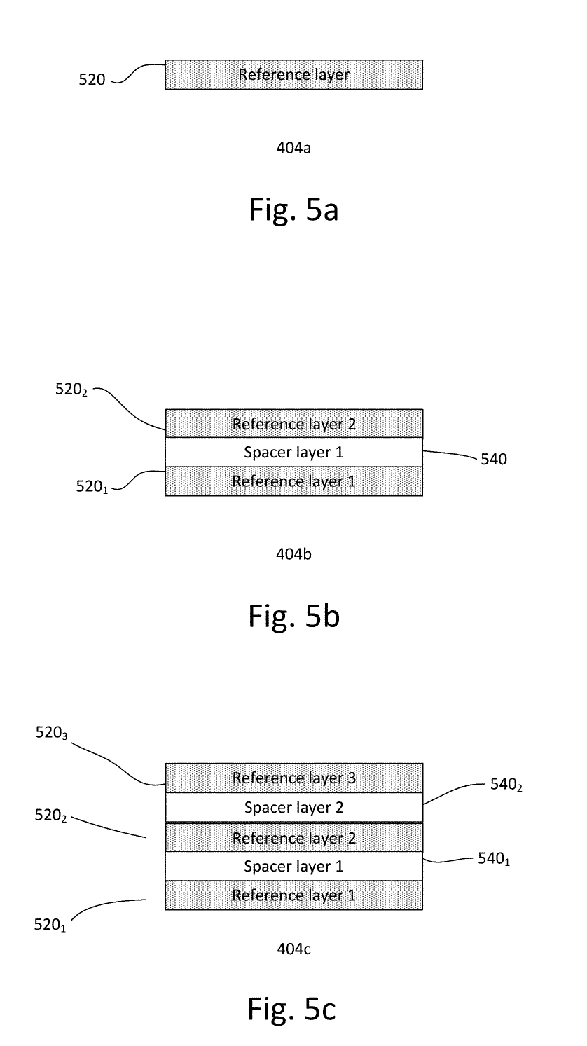

FIGS. 5a-5c show various embodiments of reference layers. The reference layer includes single and composite reference layers. Common elements may not be described or described in detail. The reference layers may be employed in a bottom pinned or top pinned pMTJ.

Referring to FIG. 5a, a reference layer 404a is shown. The reference layer is similar to that described in FIGS. 4a-4b. As shown, the reference layer includes a single magnetic reference layer 520 and is configured to have low temperature sensitivity, as previously described. The reference layer may be a low TempCo CoFeB-based magnetic reference layer or a Sm-based layer, such as a doped Sm or SmCo₅ layer. The Sm-based layer may be doped with dysprosium (Dy), Cu, Mo, W, B, Fe, Co, Zr or a combination thereof. In other embodiments, the Sm-based layer may be a SmTM layer, such as Sm₂TM₁₇ layer. Other types of SmTM layers may also be useful.

The low TempCo reference layer is configured to have almost constant temperature response for both magnetic moment (Mₛ) and magnetic anisotropy (Hₖ). This results in a low coupling field (H_{cpl}) from room temperature to reflow temperature. For example, both Mₛ and effective perpendicular magnetic anisotropy (K_{eff}) are less sensitive to temperature. In one embodiment, the composite reference layer has a low H_{cpl}. The H_{cpl} is less than 20 Oe at the reflow temperature. In one embodiment, the H_{cpl} may be about 0 Oe at room temperature, such as 25° C., and less than 20 Oe at reflow temperature, such as 260° C. The thickness of the reference layer may be about 0.7-1.5 nm. Other thicknesses may also be useful.

As previously discussed, MR and TempCo of a magnetic layer may be tuned by composition of the elements. In addition, the thickness, such as in the case of a CoFe-based magnetic layer, can affect MR and TempCo. By tuning the layer using composition and thickness, low TempCo with good MR can be achieved.

Referring to FIG. 5b, a composite reference layer 404b is shown. The composite reference layer is similar to that described in FIGS. 4a-4b. Common elements may not be described or described in detail. The composite reference layer may be employed in a bottom pinned or top pinned pMTJ with a single tunneling barrier or with dual tunneling barriers.

As shown, the composite reference layer includes first and second magnetic reference layers 520₁ and 520₂ separated by a non-magnetic metal spacer layer 540. For example, the composite layer has n magnetic reference layers separated by (n−1) non-magnetic metal spacer layers, where n=2. The first reference layer is disposed proximate to the HM layer and the second reference layer is disposed proximate to the tunneling barrier layer. A non-magnetic spacer layer of the composite reference layer may be a Ta, MO or W spacer layer. Other types of spacer layers may also be useful. The thickness of a magnetic reference layer maybe about 0.8-2 nm and the thickness of a non-magnetic metal spacer layer may be about 0.1-0.5 nm. Other thicknesses may also be useful.

The composite reference layer is configured to have low temperature sensitivity. For example, the composite reference layer is configured to have almost constant temperature response for both magnetic moment (Mₛ) and magnetic anisotropy (Hₖ). This results in a low coupling field (H_{cpl}) from room temperature to reflow temperature. For example, both Mₛ and effective perpendicular magnetic anisotropy (K_{eff}) are less sensitive to temperature. In one embodiment, the composite reference layer has a low H_{cpl} at room temperature, such as 25° C., to reflow temperature, such as 260° C. For example, the H_{cpl} may be about 0 Oe at room temperature and less than 20 Oe at reflow temperature. Low H_{cpl} improves data retention reliability.

The composite reference layer with 2 magnetic reference layers separated by a metal spacer layer may have a greater total thickness than a single reference layer. For example, the composite reference layer may be about 0.7-2.5 nm or greater while a single reference layer is about 0.7-1.5 nm. Other thicknesses may also be useful. The increased overall total thickness of the composite reference layer results in an increase in the Curie temperature. This reduces the magnetic moment response to temperature. As such, low H_{cpl} can be achieved at both room temperature as well as at reflow temperature to improve data retention reliability.

In one embodiment, the first and second magnetic reference layers are tuned to produce a low TempCo composite reference layer with good or high spin polarization, resulting in good or high MR. For example, the first magnetic reference layer is tuned with high MR while the second magnetic reference is tuned with low TempCo. In other embodiments, both the first and second magnetic reference layers are tuned with high MR. However, due to increased thickness of the composite reference layer, low TempCo can be achieved. In yet other embodiments, the first and second magnetic reference layers may be tuned to be low TempCo layers. The second magnetic reference layer, although a low TempCo layer, may be configured with a higher TempCo and higher MR than the first magnetic reference layer. Other configurations of the magnetic reference layers may also be useful.

In one embodiment, the first and second magnetic reference layers may include the same type of magnetic reference layers. For example, the first and second magnetic reference layers may be CoFe-based magnetic reference layers, such as CoFeB. Other types of CoFe-based magnetic reference layers may also be useful. In one embodiment, the first magnetic reference layer may be configured to be a low TempCo magnetic reference layer. For example, the first CoFe-based magnetic reference layer may be configured as a low Tempco magnetic reference layer. As for the second CoFe-based magnetic layer, it may be configured to be a second CoFe-based layer with high MR and low switching current density. The high MR with low switching current density may be achieved by having high spin polarization. The non-magnetic metal spacer layer may include Ta, Mo, W, Ir, Zr or a combination thereof. Other types of spacer and reference layers may also be useful.

Alternatively, the second CoFe-based layer may be configured as a low TempCo CoFe-based layer, similar to the first magnetic reference layer. For example, the second magnetic reference layer, although a low TempCo layer, may be configured to have higher TempCo than the first magnetic reference layer. In yet other embodiments, the first and second CoFe-based layers may be configured as high MR layers. However, due to increased thickness, low TempCo can be achieved for the composite reference layer. Other configurations of magnetic reference layers may also be useful.

In other embodiments, the first and second magnetic reference layers may include different types of magnetic reference layers. For example, the first reference layer may be a Sm-based magnetic reference layer. The Sm-based magnetic reference layer may include a Sm-based a SmCo-based, such as SmCo₅, reference layer. The Sm-based reference layer is configured to be a low TempCo magnetic reference layer. The Sm based layer may be doped with Dy, Cu, Mo, W, B, Fe, Co, Zr or a combination thereof. In other embodiments, the low TempCo magnetic reference layer may be Sm doped with at least one transition metal (TM). For example, the low TempCo magnetic reference layer may be a SmTM layer, such as Sm₂TM₁₇ layer. Other types of SmTM layers may also be useful.

As for the second magnetic reference layer, it may be a CoFe-based magnetic layer. The second CoFe-based layer may be configured with high MR. Alternatively, the second CoFeB based layer may be configured as a low TempCo CoFe-based layer. Providing a non-CoFe-based second magnetic reference layer may also be useful.

As described, the composite reference layer includes 2 magnetic reference layers separated by a non-magnetic metal spacer layer. The magnetic reference layers may be formed of the same or different types of magnetic layers. In the case of CoFeB, different compositions may be used to configure the layer as a high MR layer or a low TempCo layer. Providing one or both of the reference layers which are not CoFe-based layers can also be useful.

Referring to FIG. 5c, a composite reference layer 404c is shown. The composite reference layer is similar to that described in FIGS. 4a-4b. Common elements may not be described or described in detail.

As shown, the composite reference layer includes first, second and third magnetic reference layers 520₁, 520₂, and 520₃ separated by first and second non-magnetic metal spacer layers 540₁ and 540₂. For example, the composite layer has n magnetic reference layers separated by (n−1) non-magnetic metal spacer layers, where n=3. The first reference layer is disposed proximate to the HM layer, the third reference layer is disposed proximate to the tunneling barrier layer and the second reference layer is disposed between the first and second reference layers. A non-magnetic spacer layer of the composite reference layer may be a Ta, Mo or W spacer layer. Other types of spacer layers may also be useful. The thickness of a spacer layer may be about 0.1-0.5 nm. It is understood that the reference layers need not be of the same type or have the same thickness. The thickness of a magnetic reference layer maybe about 0.8-2 nm. Other thicknesses may also be useful.

The composite reference layer is configured to have low temperature sensitivity and good MR. For example, the composite reference layer is configured to have almost constant temperature response for both magnetic moment (Mₛ) and magnetic anisotropy (Hₖ). This results in a low coupling field (H_{cpl}) from room temperature to reflow temperature. For example, both Mₛ and effective perpendicular magnetic anisotropy (K_{eff}) are less sensitive to temperature. In one embodiment, the composite reference layer has a low H_{cpl}. The H_{cpl} is less than 20 Oe at the reflow temperature. A low H_{cpl} improves data retention reliability.

The composite reference layer with 3 magnetic reference layers separated by 2 metal spacer layers may have a greater total thickness than a single reference layer. The increased overall total thickness of the composite reference layer results in an increase in the Curie temperature. This reduces the magnetic moment response to temperature. As such, low H_{cpl} can be achieved at both room temperature as well as at reflow temperature, resulting in improved data retention reliability.

In one embodiment, the first reference layer is configured to be a low TempCo layer, the third reference layer is configured to be a high MR layer while the second reference layer is configured to have a lower TempCo than the third reference layer but with high MR. Other configurations of the magnetic reference layers of the composite reference layer may also be useful.

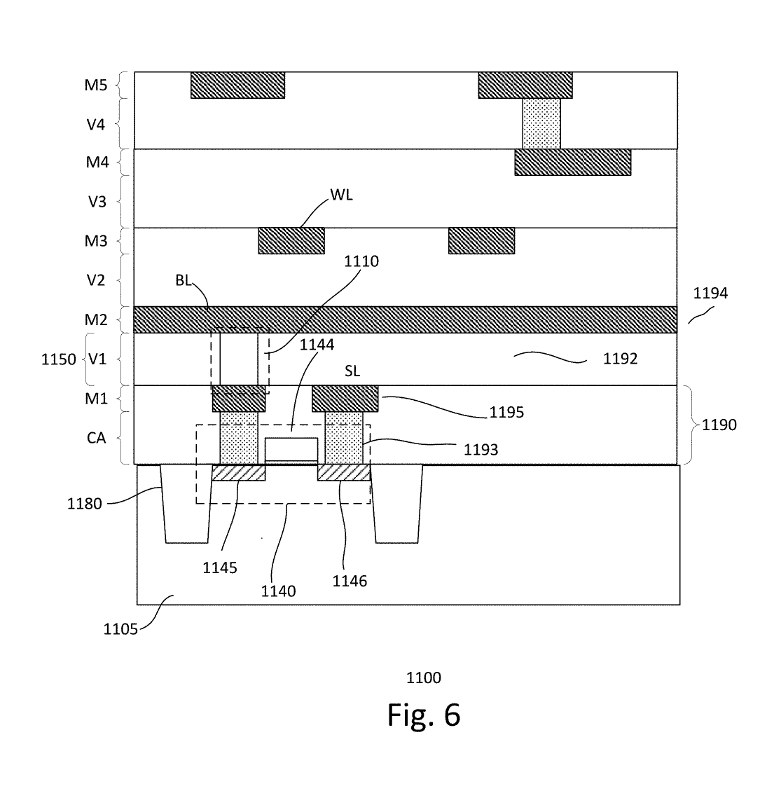

FIG. 6 shows a cross-sectional view of an exemplary embodiment of a memory cell 1100 of a device. The cross-sectional view, for example, is along a second or bitline direction of the device. The device, as shown, includes a memory cell 1100. The memory cell, for example, may be a NVM memory cell. The memory cell, in one embodiment, is a magnetoresistive NVM cell, such as a STT-MRAM cell. The memory cell, for example, includes a pMTJ stack which is the same or similar to those described in FIGS. 3a-3d, 4a-4b and 5a-5c. Common elements may not be described or described in detail.

The memory cell is disposed on a substrate 1105. For example, the memory cell is disposed in a cell region of the substrate 1105. The cell region may be part of an array region. For example, the array region may include a plurality of cell regions. The substrate 1105 may include other types of device regions (not shown), such as high voltage (HV) as well as logic regions, including low voltage (LV) and intermediate voltage (IV) device regions. Other types of regions may also be provided.

The substrate 1105, for example, is a semiconductor substrate, such as a silicon substrate. For example, the substrate 1105 may be a lightly doped p-type substrate. Providing an intrinsic or other types of doped substrates, such as silicon-germanium (SiGe), germanium (Ge), gallium-arsenic (GaAs) or any other suitable semiconductor materials, may also be useful. In some embodiments, the substrate 1105 may be a crystalline-on-insulator (COI) substrate. A COI substrate includes a surface crystalline layer separated from a crystalline bulk by an insulator layer. The insulator layer, for example, may be formed of a dielectric insulating material. The insulator layer, for example, is formed from silicon oxide, which provides a buried oxide (BOX) layer. Other types of dielectric insulating materials may also be useful. The COI substrate, for example, is a silicon-on-insulator (SOI) substrate. For example, the surface and bulk crystalline layers are single crystalline silicon. Other types of COI substrates may also be useful. It is understood that the surface and bulk layers need not be formed of the same material.

Front-end-of-line (FEOL) processing is performed on the substrate 1105. The FEOL process, for example, forms n-type and p-type devices or transistors on the substrate 1105. The p-type and n-type device form a complementary MOS (CMOS) device. The FEOL processing, for example, includes forming isolation regions, various device and isolation wells, transistor gates and transistor source/drain (S/D) regions and contact or diffusion regions serving as a substrate or well taps. Forming other components with the FEOL process may also be useful.

Isolation regions 1180, for example, serve to isolate different device regions. The isolation regions may be shallow trench isolation (STI) region. To form STI regions, trenches are formed and filled with isolation material. A planarization process, such as chemical mechanical polishing (CMP) is performed to remove excess dielectric materials, forming isolation regions. Other types of isolation regions may also be useful. The isolation regions are provided to isolate device regions from other regions.

Device wells (not shown), for example, serve as bodies of p-type and n-type transistors. Device wells are doped wells. Second type doped device wells serve as bodies of first type transistors. For example, p-type device wells serve as bodies of n-type transistors and n-type device wells serve as bodies of p-type transistors. Isolation wells may be used to isolate device wells from the substrate. The isolation wells are deeper than the device wells. For example, isolation wells encompass the device wells. The isolation wells are first type doped wells. For example, n-type isolation wells are used to isolate p-type device wells. Separate implants may be employed to form different doped device wells and isolation wells using, for example, implant masks, such as photoresist masks. The wells, for example, are formed after forming isolation regions.

Gates of transistors are formed on the substrate. For example, layers of the gate, such as gate dielectric and gate electrode are formed on the substrate and patterned to form the gates 1144. The gate dielectric may be a silicon oxide layer while the gate electrode layer may be polysilicon. The gate electrode may be doped, for example, to reduce sheet resistance. Other types of gate dielectric and gate electrode layers may also be useful. The gate dielectric layer may be formed by thermal oxidation and the gate electrode layer may be formed by chemical vapor deposition (CVD). Separate processes may be performed for forming gate dielectrics of the different voltage transistors. This is due to, for example, different gate dielectric thicknesses associated with the different voltage transistors. For example, high voltage (HV) transistor will have a thicker gate dielectric than a low voltage (LV) transistor.

The gate layers are patterned by, for example, mask and etch techniques. For example, a patterned photoresist mask may be provided over the gate layers. For example, a photoresist layer is formed over the gate layers and lithographically exposed by using a reticle. The photoresist mask layer is developed, forming a patterned photoresist mask with the desired pattern of the reticle. To improve lithographic resolution, an anti-reflective coating (ARC) layer may be provided between the gate electrode layer and the photoresist mask layer. An anisotropic etch, such as a reactive ion etch (RIE) is used to pattern the gate layers to form the gates using the patterned photoresist mask.

Doped contact regions, such as source/drain (S/D) regions and well or substrate taps are formed in exposed active regions of the substrate 1105 after forming the gates. The contact regions are heavily doped regions. Depending on the type of transistor and well tap, the contact regions may be heavily doped n-type or p-type regions. For n-type transistors, S/D regions are heavily doped n-type regions and for p-type transistors, S/D regions are heavily doped p-type regions. For well taps, they are the same dopant type as the well.

A S/D region may include lightly doped diffusion (LDD) and halo regions. A LDD region is a lightly doped region with first polarity type dopants while the halo region is a lightly doped region with second polarity type dopants. For example, the halo region includes p-type dopants for a p-type transistor while the LDD region includes n-type dopants for n-type transistors. The halo and LDD regions extend under the gate. A halo region extends farther below the gate than a LDD region. Other configurations of LDD, halo and S/D regions may also be useful.

Dielectric spacers (not shown) may be provided on the gate sidewalls of the transistors. The spacers may be used to facilitate the formation of halo, LDD and S/D regions. For example, spacers are formed after halo and LDD regions are formed. Spacers may be formed by, for example, forming a spacer layer on the substrate and anisotropically etching it to remove horizontal portions, leaving the spacers on the sidewalls of the gates. After forming the spacers, an implant is performed to form the S/D regions. Separate implants may be employed to form different doped regions using, for example, implant masks, such as photoresist mask. Well taps of the same dopant type as S/D regions are formed at the same time.

As shown, the FEOL processing forms a cell region isolated by an isolation region 1180, such as a STI region. The cell region is for a memory cell. Isolation regions may be provided to isolate columns of memory cells. Other configurations of isolation regions may also be useful. The cell region may include a cell device well (not shown). The cell device well, for example, serves as a body well for a transistor of the memory cell. The device well may be doped with second polarity type dopants for first polarity type transistors. The device well may be lightly or intermediately doped with second polarity type dopants. In some cases, a cell device isolation well (not shown) may be provided, encompassing the cell device well. The isolation well may have a dopant type which has an opposite polarity to that of the cell device well. For example, the isolation well may include first polarity type dopants. The isolation well serves to isolate the cell device well from the substrate. Well biases may be provided to bias the wells.

The cell device well may be a common well for the cell regions in the array region. For example, the cell device well may be an array well. The cell device isolation well may serve as the array isolation well. Other configurations of device and isolation wells may also be useful. Other device regions of the device may also include device and/or device isolation wells.

The memory cell includes a cell selector unit 1140 and a storage unit 1110. The FEOL forms the cell selector unit 1140 in the cell region. The cell selector unit 1140 includes a selector for selecting the memory cell. The selector, for example, may be a select transistor. In one embodiment, the select transistor is a metal oxide semiconductor (MOS) transistor. The transistor, as shown, includes first and second source/drain (S/D) regions 1145 and 1146 formed in the substrate 1105 and a gate 1144 disposed on the substrate between the S/D regions. The first S/D region 1145 may be referred to as a drain region and the second S/D region 1146 may be referred to as a source region. The S/D regions, for example, are heavily doped regions with first polarity type dopants, defining the type of transistor. For example, in the case of a n-type transistor, the S/D regions are n-type heavily doped regions. Other types of transistors or selectors may also be useful.

As for the gate 1144, it includes a gate electrode over a gate dielectric. The gate electrode may be polysilicon while the gate dielectric may be silicon oxide. Other types of gate electrode and gate dielectric materials may also be useful. A gate, for example, may be a gate conductor along a first or wordline direction. The gate conductor forms a common gate for a row of memory cells.

As discussed, a S/D region may include LDD and halo regions (not shown). Dielectric spacers (not shown) may be provided on the gate sidewalls of the transistors to facilitate forming halo, LDD and transistor S/D regions of the transistor. It is understood that not all transistors include LDD and/or halo regions.

After forming the cell selector unit 1140 and other transistors, back-end-of-line (BEOL) processing is performed. The BEOL process includes forming interconnects in interlevel dielectric (ILD) layers 1190. The interconnects connect the various components of the integrated circuit (IC) to perform the desired functions. An ILD layer includes a metal level 1194 and a contact level 1192. Generally, the metal level 1194 includes conductors or metal lines 1195 while the contact level 1192 includes contacts 1193. The conductors and contacts may be formed of a metal, such as Cu, Cu alloy, Al, W or a combination thereof. Other suitable types of metal, alloys or conductive materials may also be useful. In some cases, the conductors and contacts may be formed of the same material. For example, in upper metal levels, the conductors and contacts may be formed by dual damascene processes. This results in the conductors and contacts having the same material. In some cases, the conductors and contacts may have different materials. For example, in the case where the contacts and conductors are formed by single damascene processes, the materials of the conductors and contacts may be different. Other techniques, such as reactive ion etch (ME) may also be employed to form metal lines.

A device may include a plurality of ILD layers or levels. For example, x number of ILD levels may be provided. As illustrated, the device includes 5 ILD levels (x=5). Other numbers of ILD levels may also be useful. The numbers of ILD levels may depend on, for example, design requirement or the logic process involved. A metal level of an ILD level may be referred to as Mᵢ, where i is from 1 to x and is the i^{th} ILD level of x ILD levels. A contact level of an ILD level may be referred to as Vᵢ₋₁, where i is the i^{th} ILD level of x ILD levels.

The BEOL process, for example, commences by forming a dielectric layer over the transistors and other components are formed in the FEOL process. The dielectric layer may be silicon oxide. For example, the dielectric layer may be silicon oxide formed by chemical vapor deposition (CVD). The dielectric layer serves as a pre-metal dielectric layer or first contact layer of the BEOL process. The dielectric layer may be referred to as CA level of the BEOL process. Contacts are formed in the CA level dielectric layer. The contacts may be formed by single damascene processes. Via openings are formed in the dielectric layer using mask and etch techniques. For example, a patterned resist mask with openings corresponding to the vias is formed over the dielectric layer. An anisotropic etch, such as RIE, is performed to form the vias, exposing contact regions below, such as S/D regions and gates. A conductive layer, such as tungsten is deposited on the substrate, filling the openings. The conductive layer may be formed by sputtering. Other techniques may also be useful. A planarization process, such as CMP, is performed to remove excess conductive materials, leaving contact plugs in the CA level.

After forming contacts 1193 in the CA level, the BEOL process continues to form a dielectric layer over the substrate 1105, covering the CA level dielectric layer. The dielectric layer, for example, serves as a first metal level M₁ of the first ILD layer. The upper dielectric layer, for example, is a silicon oxide layer. Other types of dielectric layers may also be useful. The dielectric layer may be formed by CVD. Other techniques for forming the dielectric layer may also be useful.

Conductive lines are formed in the M₁ level dielectric layer. The conductive lines may be formed by a damascene technique. For example, the dielectric layer may be etched to form trenches or openings using, for example, mask and etch techniques. A conductive layer is formed on the substrate, filling the openings. For example, a Cu or Cu alloy layer may be formed to fill the openings. The conductive material may be formed by, for example, plating, such as electro or electro-less plating. Other types of conductive layers or forming techniques may also be useful. Excess conductive materials are removed by, for example, CMP, leaving a planar surface with M₁ dielectric. The first metal level M₁ and CA may be referred as a lower ILD level.

The process continues to form additional ILD layers (not shown). For example, the process continues to form upper ILD layers or levels. The upper ILD levels may include ILD level 2 to ILD level x. For example, in the case where x=5 (5 levels), the upper levels include ILD levels from 2 to 5, which include via levels V₁ to V₄ and metal levels M₂ to M₅. The number of ILD layers may depend on, for example, design requirement or the logic process involved. The upper ILD layers may be formed of silicon oxide. Other types of dielectric materials, such as low k, high k or a combination of dielectric materials may also be useful. The ILD layers may be formed by, for example, CVD. Other techniques for forming the ILD layers may also be useful.

The conductors and contacts of the upper ILD layers may be formed by dual damascene techniques. For example, vias and trenches are formed, creating dual damascene structures. The dual damascene structure may be formed by, for example, via first or via last dual damascene techniques. Mask and etch techniques may be employed to form the dual damascene structures. The dual damascene structures are filled with a conductive layer, such as copper or copper alloy. The conductive layer may be formed by, for example, plating techniques. Excess conductive materials are removed by, for example, CMP, forming conductors and contacts in an upper ILD layer.

A dielectric liner (not shown) may be disposed between ILD levels and on the substrate 1105. The dielectric liner, for example, serves as an etch stop layer. The dielectric liner may be formed of a low k dielectric material. For example, the dielectric liner may be nBLOK. Other types of dielectric materials for the dielectric liner may also be useful.

The uppermost ILD level (e.g., M₅) may have different design rules, such as critical dimension (CD), than the lower ILD levels. For example, Mₓ may have a larger CD than metal levels M₁ to Mₓ₋₁ below. For example, the uppermost metal level may have a CD which is 2× or 6× the CD of the metal levels below. Other configurations of the ILD levels may also be useful.

As shown, S/D contacts 1193 are disposed in the CA level. The S/D contacts are coupled to the first and second S/D regions of the select transistor. Other S/D contacts coupled to other S/D regions of transistors may also be provided. The CA level may include a gate contact (not shown) coupled to the gate of the select transistor. The gate contact may be disposed in another cross-section of the device. The contacts may be tungsten contacts while contact pads may be copper pads. Other types of contacts and contact pads may also be useful. Other S/D and gate contacts for other transistors may also be provided.

As described, metal lines are provided in M₁. The metal lines are coupled to the S/D contacts 1193. In one embodiment, a SL is coupled to the second S/D region 1146 of the select transistor. As for the first S/D contact 1145, it may be coupled to contact pads or island in M₁. The contact pads provide connections to upper ILD levels. The metal lines or pads may be formed of copper or copper alloy. Other types of conductive materials may also be useful.

As for the upper ILD, for example, from 2 to 5, they include contacts in the via level and contact pads/metal lines in the metal level. The contacts and contact pads provide connections from M₅ to the first S/D region 1145 of the select transistor.

A pad level (not shown) is disposed over the uppermost ILD level. For example, a pad dielectric level is disposed over Mₓ. In the case where the device includes 5 metal levels, the pad level is disposed over M₅. The pad dielectric layer, for example, may be silicon oxide. Other types of dielectric materials may also be useful. The pad dielectric layer includes pads, such as bond pads or pad interconnects for providing external interconnections to the components. Bond pads may be used for wire bonding while pad interconnects may be provided for contact bumps. The external interconnections may be input/output (I/O), power and ground connections to the device. The pads, for example, may be aluminum pads. Other types of conductive pads may also be useful. A passivation layer, such as silicon oxide, silicon nitride or a combination thereof, may be provided over the pad level. The passivation layer includes openings to expose the pads.

A dielectric liner may be disposed between the uppermost metal level and pad level. The dielectric liner, for example, serves as an etch stop layer during via etch process and it may also serve as a diffusion barrier layer for, for example, Cu layer. The dielectric liner may be a low k dielectric liner. For example, the dielectric liner may be nBLOK. Other suitable types of dielectric materials for the dielectric liner may also be useful.

The storage unit 1110 of the memory cell is disposed in a storage dielectric layer 1150. The storage dielectric layer 1150 may be a via level of an ILD level. As shown, the storage dielectric layer 1150 is V₁. Providing the storage dielectric layer at other via levels may also be useful. In other embodiments, the storage dielectric layer 1150 may be a dedicated storage dielectric layer and is not part of an interconnect level. Other configurations of storage dielectric layer may also be useful. The storage unit 1110 includes a storage element disposed between bottom and top electrodes, forming a pMTJ stack. The pMTJ stack may be pMTJ stacks as previously described, for example, in FIGS. 3a-3d, 4a-4b and 5a-5c.

In one embodiment, the bottom electrode of the storage unit is coupled to a drain of the select transistor. For example, the bottom electrode is coupled to a contact pad in the M₁ level and a via contact in the CA level. Other configurations of coupling the bottom electrode may also be useful. The top electrode is coupled to a BL. For example, the top electrode is coupled to the BL disposed in M₂. The BL is along a bitline direction. As for the source of the select transistor, it is coupled to a SL. For example, a via contact in CA is provided to couple the source region of the select transistor to SL in M₁. Providing SL in other levels may also be useful.

As for the gate of cell selector, it is coupled to a WL. The WL, for example, is along a wordline direction. The bitline and wordline directions are perpendicular to each other. As shown, the WL is disposed in M₃. The WL may be coupled to the gate by contact pads in M₂ and M₁ and via contacts in V₂ and V₁ (not shown). Other configurations of coupling the WL to the gate may also be useful. For example, the WL may be disposed in other metal levels.

Although as described, the various lines and storage element are disposed in specified dielectric levels of the backend dielectric levels, other configurations may also be useful. For example, they may be disposed in other or additional metal levels. For example, the storage element may be provided in an upper via level, such as between M₅ and M₆ (not shown). Furthermore, the device may include other device regions and components.

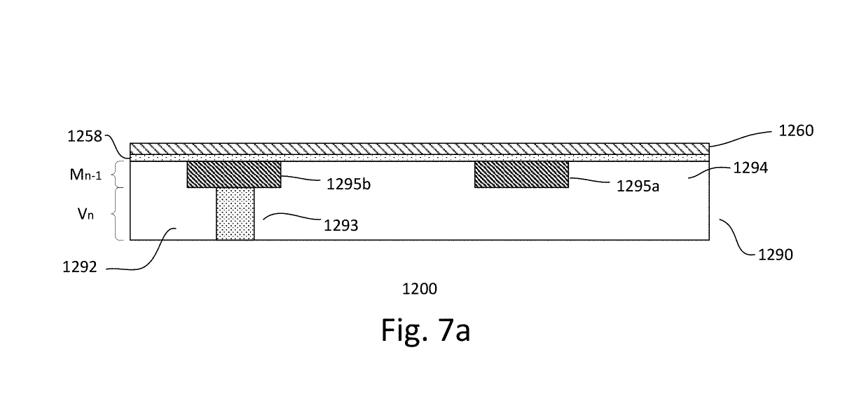

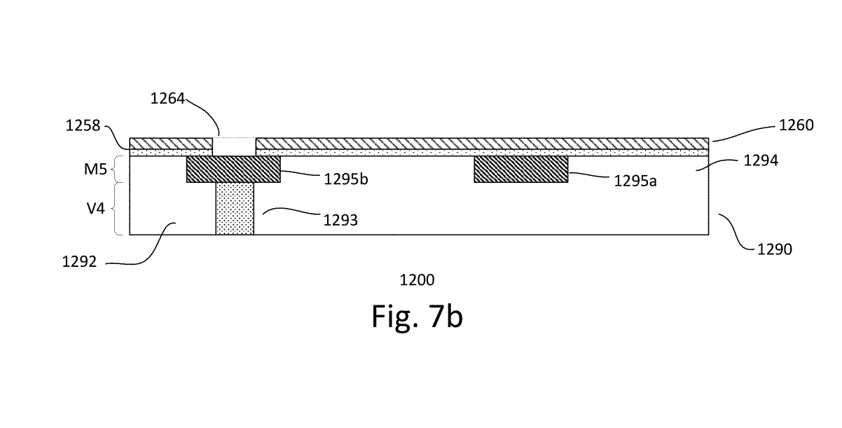

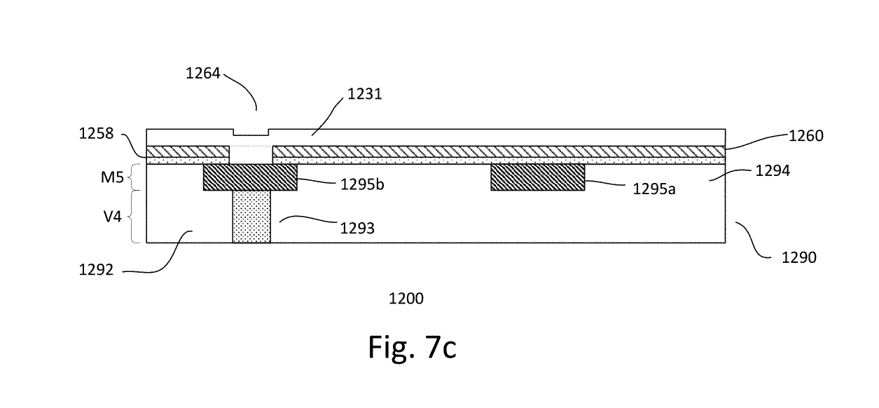

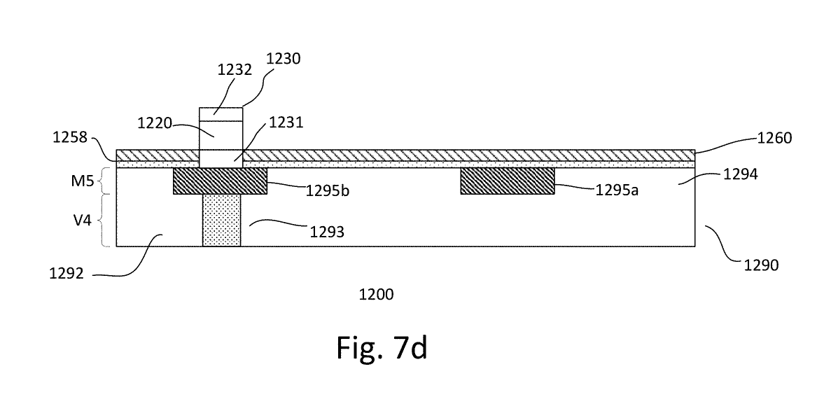

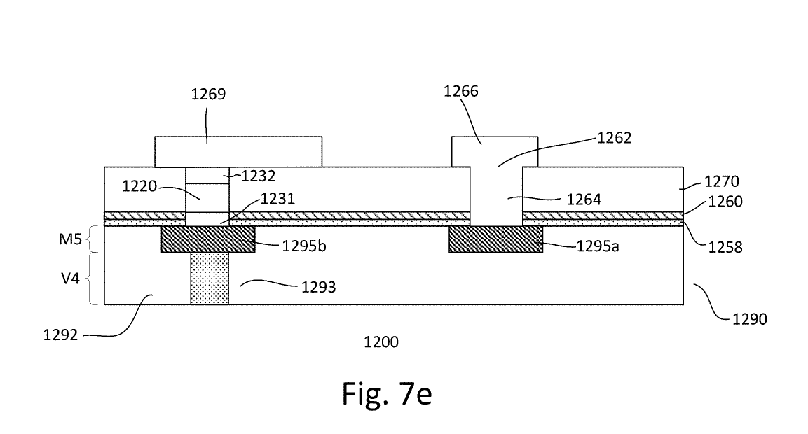

FIGS. 7a-7e show simplified cross-sectional views of an embodiment of a process for forming a device 1200. The process includes forming a memory cell. The memory cell, for example, may be a NVM memory cell. The memory cell, in one embodiment, is a magnetoresistive NVM cell, such as a STT-MRAM cell. The memory cell, for example, is similar to that described in FIG. 6. Common elements may not be described or described in detail. The cross-sectional views, for example, are along the bitline direction. Although the cross-sectional views show one memory cell, it is understood that the device includes a plurality of memory cells of, for example, a memory array. In addition, the memory cell can be formed simultaneously with CMOS logic devices on the same substrate.

The simplified cross-sectional views illustrate an upper ILD level 1290. For example, a substrate (not shown) has been processed with FEOL and BEOL processing, as already described, to include the upper ILD level. FEOL processing, for example, forms transistors, including a select transistor of the memory cell. Other types of devices may also be formed on the same substrate. BEOL processing forms interconnects in ILD levels. The upper ILD level includes a via level 1292 and a metal level 1294. For example, the upper ILD level includes V₄ and M₅. The via level, as shown, includes via contacts 1293 while the metal level includes interconnects. For example, interconnect 1295b is a cell contact pad for coupling to a storage unit and interconnect 1295a is coupled to a pad interconnect. The interconnects, for example, are copper interconnects. Other suitable types of interconnects may also be useful.

Referring to FIG. 7a, a dielectric liner 1258, in one embodiment, is disposed above the metal level. The dielectric liner, for example, serves as an etch stop layer. The dielectric liner may be a low k dielectric liner. For example, the dielectric liner may be nBLOK. Other types of dielectric materials for the dielectric liner may also be useful. The dielectric liner, for example, is formed by CVD. Other suitable techniques for forming the dielectric liner may also be useful.

The process continues to form a dielectric layer. A lower dielectric layer 1260 is formed on the dielectric liner 1258. The lower dielectric layer, in one embodiment, includes oxide materials. The lower dielectric layer may be formed by CVD. Other suitable forming techniques or suitable thicknesses for the lower dielectric layer may also be useful.

In FIG. 7b, the lower dielectric layer 1260 and the dielectric liner 1258 are patterned to form a storage unit opening 1264. The storage unit opening 1264, for example, is a via opening for accommodating a lower portion of a subsequently formed storage stack. The storage unit opening 1264 exposes a cell contact pad 1295b in the metal level below. The opening may be formed by mask and etch techniques. For example, a patterned photoresist mask may be formed over the lower passivation layer, serving as an etch mask. An etch, such as RIE, may be performed to pattern the lower passivation layer using the patterned resist etch mask. In one embodiment, the etch transfers the pattern of the mask to the lower passivation layer, including the dielectric liner to expose the cell contact pad below.

Referring to FIG. 7c, the process continues to form a storage stack. As shown, a bottom electrode layer 1231 is formed on the substrate, filling the opening and covering the dielectric layer. Excess electrode material may be removed by, for example, CMP, forming a bottom electrode in the opening. The CMP forms a planar top surface between the bottom electrode and dielectric layer.

Referring to FIG. 7d, a storage stack is formed. The storage stack may be a magnetic storage stack. The magnetic storage stack is, for example, a pMTJ stack, similar to those describe in FIGS. 3a-3d, 4a-4b and 5a-5c. The pMTJ stack may include various embodiments of the magnetic free layer similar to those described in FIGS. 5a-5c. The pMTJ stack forms a storage unit of a MRAM cell, similar to those described in FIG. 6.

The pMTJ stack, for example, includes a storage stack disposed between top and bottom electrodes. The bottom electrode is coupled to a contact pad in the metal level below. For example, the bottom electrode is coupled to a contact pad 1295b in M₅. This provides connections of the pMTJ stack to the first S/D region 1145 of the cell select transistor as described in FIG. 2a. As for the top electrode, it is exposed at the top of the intermediate dielectric layer.

The various layers of the pMTJ stack are formed on the substrate. For example, the various layers of the pMTJ stack are sequentially formed over the lower passivation layer and fill the opening. After the opening 1264 is formed, a bottom electrode layer 1231, such as Ta or TaN is deposited over the lower passivation layer and fills the opening. A chemical mechanical polishing (CMP) process is applied to form an embedded bottom electrode in the opening 1264 and remove excess bottom electrode layer in other areas. Other suitable bottom electrode materials and techniques may be employed. The bottom electrode 1231 fills the opening and the surface is flat.

The process continues to form remaining layers of the pMTJ stack, such as the storage stack 1220 and the top electrode 1232, on top of the bottom electrode by physical vapor deposition (PVD) process. The layers of the pMTJ stack are patterned to form the pMTJ stack 1230 as shown. Patterning the layers maybe achieved with a non-conducting mask and etch techniques. After forming the pMTJ stack 1230, the non-conducting mask layer used to pattern the pMTJ stack is removed if dielectric ARC or oxide hard mask layer is used. Other suitable techniques for forming the pMTJ stack may also be useful.

In one embodiment, the substrate is subjected to an alloying process. The alloying process includes annealing the substrate to around 400° C. with duration of about 1-2 hours and with hydrogen ambient. Other annealing parameters may also be useful.

An intermediate dielectric layer 1270 which serves as a storage dielectric layer is formed on the substrate, as shown in FIG. 7e. The dielectric layer is formed over the lower dielectric layer 1260 and sufficiently covers the pMTJ stack. The intermediate dielectric layer, for example, is silicon oxide. Other types of intermediate dielectric layers may also be useful. The intermediate dielectric layer may be formed by CVD. Other techniques for forming the dielectric layer may also be useful.

A planarizing process is performed on the substrate, planarizing the intermediate dielectric layer. The planarizing process, for example, is a CMP process. The CMP process produces a planar top surface between the top of the pMTJ stack and the intermediate dielectric layer. The intermediate dielectric layer is patterned to form a via opening 1276. The via opening is patterned by mask and etch techniques. The via opening penetrates through the various dielectric layers and the dielectric liner. This exposes the interconnect 1295a in the lower metal level. After forming the via opening, the mask layer is removed. For example, the mask and ARC layers are removed.

A conductive layer is formed on the substrate. The conductive layer covers the intermediate dielectric layer and pMTJ stack as well as fills the via opening. The conductive layer should be sufficiently thick to serve as a metal line or an interconnect. The conductive layer, for example, includes a copper layer. Other suitable types of conductive layers may also be useful. The conductive layer may be formed by, for example, sputtering. Other suitable techniques for forming the conductive layer may also be useful.

The conductive layer is patterned to form a metal line 1269 and an interconnect 1266. Patterning the conductive layer to form the metal line and interconnect may be achieved by mask and etch techniques. For example, a patterned photoresist mask (not shown) may be formed over the conductive layer. An etch, such as RIE, may be used to pattern the conductive layer with a patterned resist mask. In one embodiment, the interconnect 1266 includes a via contact 1264 in the via opening and a contact 1262 over the intermediate dielectric layer 1270. The metal line 1269, for example, may serve as the BL. After patterning the conductive layer, the mask layer is removed. For example, the mask and ARC layers are removed.

Additional processes may be performed to complete the formation of the device. For example, the processes may include forming additional ILD levels, pad level, passivation level, pad opening, dicing, assembly and testing. Other types of processes may also be performed.

Although the storage stack of the memory cell as described above includes a pMTJ stack such as that shown in FIGS. 3a-3d, 4a-4b and 5a-5c, it is understood that other suitable configurations and other types of pMTJ stack may be used. In addition, the process as described in FIGS. 7a-7e is also applicable to other suitable types of memory cell, such as but not limited to memory cells which are sensitive to high temperature processing.

The present disclosure may be embodied in other specific forms without departing from the spirit or essential characteristics thereof. The foregoing embodiments, therefore, are to be considered in all respects illustrative rather than limiting the present disclosure described herein. Scope of the present disclosure is thus indicated by the appended claims, rather than by the foregoing description, and all changes that come within the meaning and range of equivalency of the claims are intended to be embraced therein.

1. A method of forming a device comprising:
providing a substrate comprising circuit component formed on a substrate surface;
performing back-end-of-line (BEOL) processing to form a BEOL dielectric layer over the substrate, wherein the BEOL dielectric layer comprises a plurality of interlevel dielectric (ILD) levels; and
forming a perpendicular magnetic tunnel junction (pMTJ) stack between adjacent ILD levels of the BEOL dielectric layer, the pMTJ stack is disposed between top and bottom electrodes, and wherein forming the pMTJ stack comprises
forming various layers of the pMTJ on the bottom electrode, wherein the various layers include,
a magnetic fixed layer, wherein the magnetic fixed layer includes a magnetic reference layer with a low temperature coefficient (TempCo) and good spin polarization, which results in good magnetoresistance ratio (MR),
a first tunnelling barrier layer, and
a magnetic free layer.

2. The method of claim 1 wherein:
forming the magnetic reference layer comprises forming a composite reference layer comprising forming n magnetic reference layers separated by n−1 non-magnetic spacer layers;
an i^{th} magnetic reference layer in which i=n is equal to the composite reference layer disposed closest to the first tunnel barrier layer and i=1 is the composite reference layer disposed farthest from the first tunnel barrier; and
the composite reference layer is configured with low TempCo and good MR by tuning the TempCo and MR of the magnetic reference layers.

3. The method of claim 2 wherein tuning the TempCo and MR of the magnetic reference layers can be achieved by varying materials of the magnetic reference layers, compositional range of elements of the magnetic reference layers, thickness of the magnetic reference layers or a combination thereof.

4. The method of claim 2 wherein:
the magnetic reference layer closest to the first tunnel barrier is tuned with the highest MR; and
the magnetic reference layers away from the first tunnel barrier are tuned with decreasing TempCo, with the magnetic reference layer farthest form the first tunnel barrier tuned with the lowest TempCo.

5. The method of claim 2 wherein:
the composite reference layer comprises first and second magnetic reference layers (n=2) separated by a first spacer layer (n−1=1);
the first magnetic reference layer (i=1) is tuned for low TempCo; and
the second magnetic reference layer (i=2 or n) is tuned for high MR.

6. The method of claim 2 wherein:
the composite reference layer comprises first and second magnetic reference layer (n=2); and
the first and second magnetic reference layer (i=1) are tuned for low TempCo.

7. The method of claim 6 wherein the second magnetic reference layer is tuned with a higher MR than the first magnetic layer.

8. The method of claim 2 wherein:
the composite reference layer comprises first, second and third magnetic reference layers (n=3) separated by first and second spacer layers (n−1=2);
the first magnetic reference layer (i=1) is tuned with the lowest TempCo;
the second magnetic reference layer (i=2 or n) is tuned with higher TempCo and higher MR than the first magnetic reference layer; and
the third magnetic reference layer (i=3) is tuned with the highest MR.

9. The method of claim 2 wherein the n magnetic reference layers comprise magnetic layers which are cobalt-iron-based (CoFe-based), samarium-based magnetic layers or a combination thereof.

10. The method of claim 2 wherein the n−1 non-magnetic comprise tantalum (Ta), molybdenum (Mo), tungsten (W), iridium (Ir) and zirconium (Zr) or a combination thereof.

11. The method of claim 1 wherein the pMTJ stack comprises a single tunnelling barrier bottom pinned pMTJ stack in which sequentially forming the various layers comprises:
forming the magnetic fixed layer on the bottom electrode;
forming the first tunnelling barrier layer on the magnetic fixed layer;
forming the magnetic free layer on the first tunnelling barrier layer;
forming a cap layer on the magnetic free layer; and
forming the top electrode on the cap layer.

12. The method of claim 1 wherein the pMTJ stack comprises a dual tunnelling barrier bottom pinned pMTJ stack in which sequentially forming the various layers comprises:
forming the magnetic fixed layer on the bottom electrode;
forming the first tunnelling barrier layer on the magnetic fixed layer;
forming the magnetic free layer on the first tunnelling barrier layer;
forming a second tunnelling barrier layer on the magnetic free layer; and
forming the top electrode over the second tunnelling barrier layer.

13. The method of claim 1 wherein the pMTJ stack comprises a single tunnelling barrier top pinned pMTJ stack in which sequentially forming the various layers comprises:
forming the magnetic free layer on the bottom electrode;
forming the first tunnelling barrier layer on the magnetic free layer;
forming the magnetic fixed layer on the first tunnelling barrier layer; and
forming the top electrode on the magnetic fixed layer.

14. The method of claim 1 wherein the pMTJ stack comprises a dual tunnelling barrier top pinned pMTJ stack in which sequentially forming the various layers comprises:
forming a second tunnelling barrier layer on the bottom electrode;
forming the magnetic free layer on the second tunnelling barrier layer;
forming the first tunnelling barrier layer on the magnetic free layer;
forming the magnetic fixed layer on the first tunnelling barrier layer; and
forming the top electrode on the magnetic fixed layer.

15. A device comprising:
a substrate comprising circuit component on a substrate surface;
a back-end-of-line (BEOL) dielectric layer disposed over the substrate, wherein the BEOL dielectric layer comprises a plurality of interlevel dielectric (ILD) levels; and
a perpendicular magnetic tunnel junction (pMTJ) stack between adjacent ILD levels of the BEOL dielectric layer, the pMTJ stack is disposed between top and bottom electrodes, and wherein the pMTJ stack comprises various layers on the bottom electrode, wherein the various layers include,
a magnetic fixed layer, wherein the magnetic fixed layer includes a magnetic reference layer with a low temperature coefficient (TempCo) and good spin polarization, which results in good magnetic ratio (MR),
a first tunnelling barrier layer, and
a magnetic free layer.

16. The device of claim 15 wherein:
the magnetic reference layer comprises a composite reference layer having n magnetic reference layers separated by n−1 non-magnetic spacer layers;
an i^{th} magnetic reference layer in which i=n is equal to the composite reference layer disposed closest to the first tunnel barrier layer and i=1 is the composite reference layer disposed farthest from the first tunnel barrier; and
the composite reference layer is configured with low TempCo and good MR by tuning the TempCo and MR of the magnetic reference layers.

17. The method of claim 16 wherein the TempCo and MR of the magnetic reference layers can be tuned by varying materials of the magnetic reference layers, compositional range of elements of the magnetic reference layers, thickness of the magnetic reference layers or a combination thereof.

18. The method of claim 2 wherein:
the composite reference layer comprises first and second magnetic reference layer (n=2); and
the first and second magnetic reference layer (i=1) are tuned for low TempCo.

19. The method of claim 16 wherein the n magnetic reference layers comprise magnetic layers which are cobalt-iron-based (CoFe-based), samarium-based magnetic layers or a combination thereof.

20. A method of forming a device comprising:
providing a substrate comprising circuit component formed on a substrate surface;
performing back-end-of-line (BEOL) processing to form a BEOL dielectric layer over the substrate, wherein the BEOL dielectric layer comprises a plurality of interlevel dielectric (ILD) levels; and
forming a perpendicular magnetic tunnel junction (pMTJ) stack between adjacent ILD levels of the BEOL dielectric layer, the pMTJ stack is disposed between top and bottom electrodes, and wherein forming the pMTJ stack comprises
forming various layers of the pMTJ on the bottom electrode, wherein the various layers include,
a magnetic fixed layer, wherein the magnetic fixed layer includes a composite magnetic reference layer with n magnetic reference layers separated by n−1 spacer layers, the composite magnetic reference layer is tuned a low temperature coefficient (TempCo) and good spin polarization, which results in good magnetic ratio (MR),
a first tunnelling barrier layer, and
a magnetic free layer.
